(19) United States
(12) Patent Application Publication
(10) Pub. No.: US 2025/0062590 A1
(43) Pub. Date: Feb. 20, 2025

(54) NONLINEAR PHOTONIC CHIP INTEGRATED WITH A SEMICONDUCTOR LASER

(71) Applicant: PINC Technologies Inc., Pasadena, CA (US)

(72) Inventors: Luis LEDEZMA, La Crescenta, CA (US); Alireza MARANDI, Pasadena, CA (US)

(21) Appl. No.: 18/805,238

(22) Filed: Aug. 14, 2024

Related U.S. Application Data
(60) Provisional application No. 63/547,458, filed on Nov. 6, 2023.
(60) Provisional application No. 63/533,119, filed on Aug. 16, 2023.

(51) Int. Cl. H01S 5/00; H01S 5/06; H01S 5/10; H01S 5/50

(52) U.S. Cl. CPC H01S 5/0092; H01S 5/0614; H01S 5/101; H01S 5/5054

(57) ABSTRACT

A semiconductor laser and a photonic nonlinear circuit chip are integrated together. The nonlinear circuit chip may include a nonlinear waveguide configured or controlled to enable sum-frequency generation, difference-frequency generation, second-harmonic generation, parametric amplification, or other nonlinear processes. Coupling between the semiconductor laser and the nonlinear circuit may be optimized by mode-matching, while back-reflections are minimized by diverting the reflections so that optical isolators are not needed. The integration of the semiconductor laser and the nonlinear photonic circuit chip enables nonlinear optical processing using a compact and scalable platform in a flexible manner that is compatible with different types of semiconductor lasers and different operation regimes. An additional input is provided so users can input an optical signal into the photonic chip for processing therein. In some examples, the photonic chip is configured with pump resonators, such as racetrack resonators. Method and device examples are described herein.

### CROSS-REFERENCE TO RELATED APPLICATIONS

This application claims priority under 35 U.S.C. § 119 to U.S. Provisional Patent Application No. 63/533,119 filed on Aug. 16, 2023, entitled, “Nonlinear photonic chip integrated with semiconductor lasers” and also to U.S. Provisional Patent Application No. 63/547,458, filed on Nov. 6, 2023, entitled, “Nonlinear photonic chip with resonant pump,” the entire contents of both of which are incorporated herein by reference as if fully set forth below in its entirety and for all applicable purposes.

### FIELD

The subject matter described herein relates to photonic devices. More particularly, the subject matter relates, in some examples, to nonlinear photonic chips for use with semiconductor lasers.

### INTRODUCTION

The quest for miniaturization and cost reduction of optical components has led to the development of compact lasers in the form of semiconductor lasers, including laser diodes and quantum cascade lasers. However, not all optical wavelengths lend themselves to generation using compact semiconductor devices, especially at low cost. This has led to relatively few low-cost options for only a few wavelengths, typically in the near-infrared wavelength range, while other wavelengths are either not available at all, or only available from expensive and difficult to operate devices.

The scalable generation of hard to obtain wavelengths using well-developed and inexpensive mid-infrared semiconductor lasers remains an important problem to be solved.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

One aspect of the disclosure provides an integrated optical device that includes a semiconductor laser and a photonic chip integrated with the semiconductor laser. The photonic chip includes: a first input component configured to receive a first optical signal from the semiconductor laser; a second input component configured to receive a second optical signal; an optical multiplexer configured to combine at least a portion of the first optical signal and at least a portion the second optical signal to provide a combined signal with combined optical waves; and a nonlinear waveguide configured to receive the combined optical waves and cause the combined optical waves to interact with one another to produce at least one output optical wave, wherein the interaction comprises at least one nonlinear process.

Another aspect of the disclosure provides a method for use with an integrated optical device that includes a photonic chip integrated with the semiconductor laser. The method includes: receiving a first optical signal into the photonic chip from the semiconductor laser; receiving a second optical signal into the photonic chip from an external source; combining at least a portion of the first optical signal and at least a portion the second optical signal within the photonic chip to provide a combined signal with combined optical waves; and routing the combined optical waves through a nonlinear waveguide of the photonic chip to cause the combined optical waves to interact with one another to produce at least one output optical wave, wherein the interaction comprises at least one nonlinear process.

Yet another aspect of the disclosure provides an integrated optical device that includes: a coherent optical source configured to generate a first coherent optical signal; and a thin-film photonic chip integrated with the coherent optical source. The photonic chip includes: an optical device configured to combine at least a portion of the first coherent optical signal and at least a portion a second coherent optical signal provided by an external source to generate a combined signal with combined optical waves; and a nonlinear waveguide configured to receive the combined optical waves and cause the combined optical waves to interact with one another to produce at least one output optical wave, wherein the interaction comprises at least one nonlinear process.

### BRIEF DESCRIPTION OF THE DRAWINGS

FIG. 1 is a schematic block diagram illustrating an exemplary frequency converter configured with discrete components, including one or more discrete nonlinear components.

FIG. 2 is a block diagram of an exemplary embodiment of an integrated photonic device, which may function as a frequency converter, in accordance with some aspects of the disclosure.

FIG. 3 is a stylized top view representation an embodiment of an integrated photonic chip, in accordance with some aspects of the disclosure.

FIG. 4A illustrates a top view of an exemplary embodiment of a coupling portion of a photonic chip that uses a linear taper, in accordance with some aspects of the disclosure.

FIG. 4B is a graph illustrating wavelength width vs a power coupling coefficient for a tapered waveguide, in accordance with aspects of the disclosure.

FIG. 5A illustrates a portion of a photonic chip showing an output waveguide and an output chip facet of the photonic chip, in accordance with some aspects of the disclosure.

FIG. 5B illustrates a portion of another photonic chip showing an output waveguide and an output chip facet of the photonic chip, in accordance with some aspects of the disclosure.

FIG. 6 is a stylized top view representation an embodiment of an integrated photonic chip having laser cavity extending into the chip, in accordance with some aspects of the disclosure.

FIG. 7 illustrates an exemplary embodiment of a photonic device configured for spectroscopy that uses a tunable telecom laser as an external input, in accordance with some aspects of the disclosure.

FIG. 8 illustrates an exemplary embodiment of a photonic device configured for parametric amplification, in accordance with some aspects of the disclosure.

FIG. 9 is a graph showing gain for an amplifier for a ridge waveguide optical device and for a thin-film lithium niobate (TLFN) platform, where the TLFN platform is configured in accordance with some aspects of the disclosure.

FIG. 10 is a stylized top view representation an embodiment of an integrated photonic chip that employs a racetrack resonator, in accordance with some aspects of the disclosure.

FIG. 11 is a stylized top view representation another embodiment of an integrated photonic chip that employs a racetrack resonator, in accordance with some aspects of the disclosure.

FIG. 12 is a stylized top view representation yet another embodiment of an integrated photonic chip that employs a racetrack resonator, in accordance with some aspects of the disclosure.

FIG. 13 is a stylized top view representation an embodiment of an integrated photonic chip that employs a linear resonator, in accordance with some aspects of the disclosure.

FIG. 14 illustrates pump signal walk-off, in accordance with some aspects of the disclosure.

FIG. 15 illustrates an exemplary embodiment of a photonic device configured for use as an infrared detector, in accordance with some aspects of the disclosure.

FIG. 16 illustrates an exemplary embodiment of a coupling section for use with an integrated photonic chip, in accordance with some aspects of the disclosure.

FIG. 17 illustrates exemplary embodiments of applications for use by an integrated photonic chip, in accordance with some aspects of the disclosure.

FIG. 18 is a block diagram of an exemplary embodiment of an integrated optical device, in accordance with some aspects of the disclosure.

FIG. 19 is a block diagram of another exemplary embodiment of an integrated optical device, in accordance with some aspects of the disclosure.

FIG. 20 is a flow diagram of an exemplary method for use with an integrated optical device that includes a thin-film photonic chip integrated with a semiconductor laser, in accordance with some aspects of the disclosure.

### DETAILED DESCRIPTION

In the following detailed description, reference is made to the accompanying drawings, which form a part thereof. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

### Overview

As noted above, the scalable generation of hard to obtain wavelengths using well-developed and inexpensive mid-infrared semiconductor lasers remains an important problem to be solved. Efforts to provide low-cost and compact frequency converters for use with semiconductor lasers have so far met with limited success. One option is to exploit nonlinear processes to perform the frequency conversion. Frequency converters based on the nonlinear optical processes have been developed, but they mostly use large bulk crystals and large area waveguides, which have a limited functionality since such devices cannot be readily integrated with additional components including low-cost semiconductor lasers.

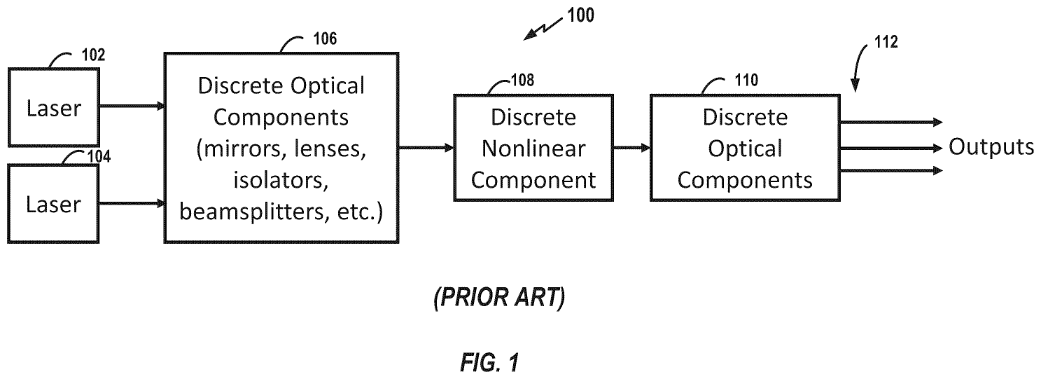

Predecessor optical frequency converters that employ nonlinear components have used discrete components. FIG. 1 illustrates an exemplary frequency converter 100 configured with discrete components, including one or more discrete nonlinear components. Briefly, device 100 includes a pair of lasers 102 and 104 that feed light signals into one or more discrete optical components 106, such as mirrors, lenses, isolators, signal splitters, etc., which may be configured to combine the light signals from the lasers. The combined signal is then fed into a discrete nonlinear component 108, which in turn feeds nonlinearly processed optical signals into one or more additional discrete optical components 110 to provide various outputs 112.

Devices of the type shown in FIG. 1 are typically bulky and expensive and so it would be advantageous to instead integrate the linear and nonlinear components to reduce cost and size. However, there are several challenges related to the integration of nonlinear elements with semiconductor lasers, including the relatively low power levels of semiconductor diodes and their large susceptibility to optical feedback. The low power level poses stringent requirements on the coupling losses between elements, while the susceptibility to optical feedback poses strict requirements on the magnitude of back-reflections to the laser. Attempts have been made to solve the feedback problem using large, bulky, and expensive isolators in-between the semiconductor lasers and the nonlinear element, but the additional loss from the isolator further hinders satisfying the requirement for low coupling losses.

Herein, an integrated photonic device is described with linear and nonlinear components for use as a frequency converter or for other applications.

In some aspects, a semiconductor laser and a photonic integrated nonlinear circuit are integrated together. The coupling between the semiconductor laser and the nonlinear circuit is optimized by mode-matching, while back-reflections are minimized by diverting the reflections. This is accomplished without optical isolators. The integration of the semiconductor laser and the nonlinear circuit enables difference-frequency generation (DFG) and sum-frequency generation (SFG) in a compact and scalable platform in a flexible manner that is compatible with different types of semiconductor lasers and different operation regimes. An additional input is provided so users can input an optical signal into the device for processing. Note that, herein, the term “optical” is not limited to merely the visible EM spectra but includes, e.g., infrared and ultraviolet light.

In some embodiments, the integrated device includes edge-emitting semiconductor lasers, directly coupled to a photonic circuit chip, which implements the nonlinear processes as well as the combining and splitting of input and output optical waves. The device can also be used with surface emitting lasers, mounted directly on top of the photonic chip. In both cases, the back-reflections are minimized by the chip internal design and its output facet. The device may also be used as an amplifier since the DFG process is physically the same as that of parametric amplification. The signal to be amplified may be provided by the user through the additional input. In some embodiments, the light from the semiconductor laser can be coupled to a resonator in the photonic chip, producing resonant enhancement of the semiconductor laser light that leads to a more efficient nonlinear interaction.

In one aspect, the integrated device is used as a source for spectroscopy, with a tunable output in the mid-infrared, by having a tunable semiconductor laser, a tunable additional input laser provided by the user, or a combination of both. In other aspects, the integrated device may be used as a detector of infrared light, with the light to be detected provided by the user through the additional port, and with the nonlinear chip producing an SFG signal in the near-infrared or visible wavelength range, with such signal being readily detected by inexpensive detectors (e.g., silicon detectors).

Thus, in some aspects, the photonic device exploits the integration of semiconductor lasers with a thin-film nonlinear photonic chip. Using a thin-film photonic chip provides various advantages. For example, it is possible to integrate input multiplexers to combine the inputs and output de-multiplexers to separate the outputs, therefore eliminating the need for a potentially large number of discrete optical components (as in FIG. 1).

The thickness of the thin-film can be chosen or selected so as to improve the coupling between the nonlinear chip and the semiconductor laser. Furthermore, one or more optical mode converters can be provided on the chip. For example, one can be configured to closely match the mode size of the semiconductor laser to that of the nonlinear waveguide to thereby obtain a large coupling efficiency between the laser and chip. Another can be configured to match mode sizes at the inputs and outputs of the chip. Still further one or more mode filters can be provided and configured, for example, to filter out (or dampen) some modes relative to other modes. The use of thin-film can also provide for large optical confinement with small mode areas and correspondingly large optical intensities that improve the nonlinear efficiency for the DFG/SFG processes, thus enabling better utilization of the limited optical power available from semiconductor lasers.

### Exemplary Embodiments

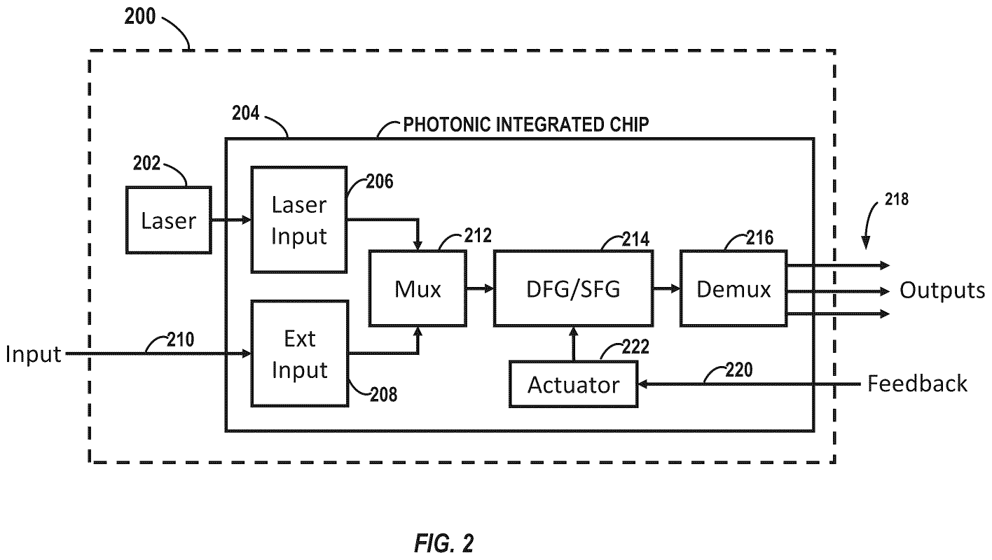

FIG. 2 is a block diagram of an exemplary embodiment of an integrated photonic device 200, which may function as a frequency converter. A semiconductor laser 202 is coupled to a photonic integrated chip 204. The photonic integrated chip 204 includes a laser input component 206 and an external input component 208, which can receive an input optical signal provided by a user along input line 210. Optical signals received via laser input 206 and external input 208 (which may have substantially different wavelengths) are applied to a wideband optical multiplexer (MUX) 212 and the resulting combined signal is applied to a DFG/SFG component 214, which may be a nonlinear waveguide. The output of the nonlinear component 214 is fed into an optical demultiplexer (DEMUX) 216, which provides two or more output signals 218. The output signals 218 may be applied, for example, to an external device (not shown). Feedback along line 220 from the external device may be received via an actuator 222, which applies the feedback signals to the nonlinear DFG/SFG component 214.

The laser input component 206 is configured to optimize the coupling between the laser 202 and the chip 204. The external input 208 is provide so users can supply their own light sources. The wideband multiplexer (MUX) 212 is provided for combining input signals having substantially different wavelengths. The nonlinear waveguide DFG/SFG component 214 can be phase-matched to generate the sum-frequency or the difference-frequency between the input signals. The demultiplexer 216 is provided to separate the output signals from the nonlinear waveguide into separate wavelength channels. The actuator 222 modifies the phase-matching of the nonlinear waveguide, potentially according to a feedback signal. Although not shown in FIG. 2, the overall system may include one or more controllers to control semiconductor laser 202 and, in some examples, to also control an external device that provides the user input optical signal 210. The controller(s) may also control the feedback signal applied to the actuator 222. The controller(s) may include computer processors or processing circuits.

Note that the photonic integrated chip 204 includes at least one nonlinear component and various linear components integrated on the chip. The DFG/SFG component 214 may be a nonlinear waveguide that is phase-matched to generate a sum-frequency (SF) or a difference-frequency (DF) between two or more input signals (received from the MUX 212). The linear components include: (a) laser input component 206, which may be configured to optimize the coupling between the laser 202 and the chip 204; (b) external input 208, provided so users can supply their own light sources; (c) wideband multiplexer 212 for combining input signals having substantially different wavelengths; (d) demultiplexer 216 for separating output signals into separate wavelength channels; and (e) actuator 222 that can modify the phase-matching of the nonlinear waveguide, potentially according to feedback signal 220. Thus, linear and nonlinear components are integrated together on a single thin-film photonic chip.

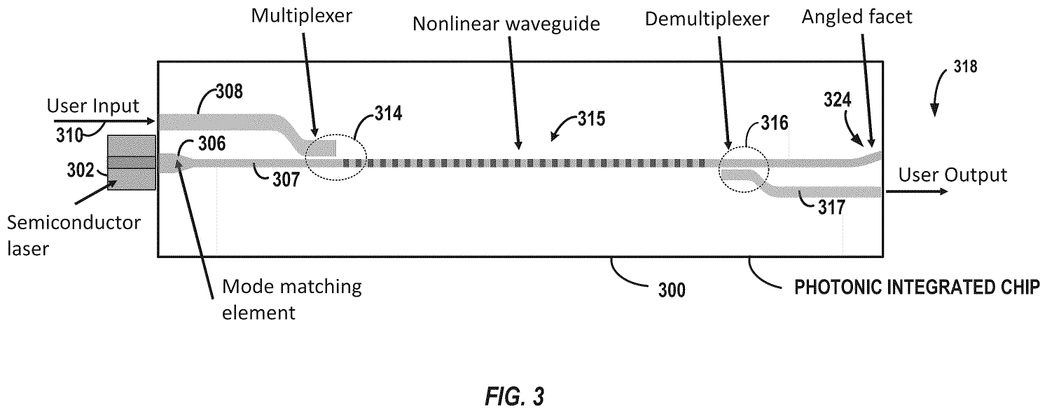

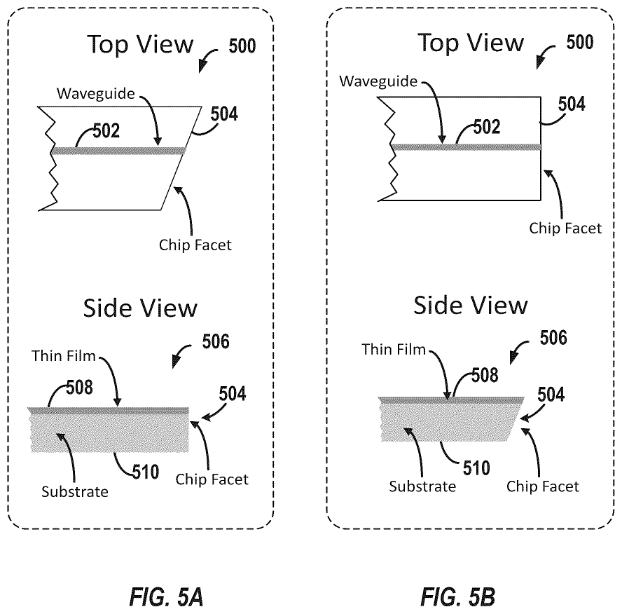

FIG. 3 is a stylized top view representation an embodiment (not to scale) of an integrated photonic chip 300, showing physical embodiments of some of the features shown in block diagram form in FIG. 2. A semiconductor laser 302 is directly mounted to a mode matching input element 306 of a waveguide 307 of the chip 300. The mode matching input element 306 serves as the laser input component for the chip. An input optical signal may be fed into waveguide 308, which serves as the external input component of the chip 300. Waveguides 307 and 308 are coupled to form a multiplexer 314 as a waveguide coupler. The combined optical signal is applied to a nonlinear waveguide 315, which provides the nonlinear DFG/SFG component of the chip 300. Periodic poling is used for phase matching. Another waveguide 317 is coupled to nonlinear waveguide 315 at its far end to form a demultiplexer 316, which provides two or more output signals 318. The output signal is also output from the main waveguide 315 via an angled facet at the end of waveguide 324 (with the angled facet provided to minimize the back-reflections to the semiconductor laser as will be described below with reference to FIG. 5A). Note that in the example of FIG. 3, no feedback or actuator are provided (as in FIG. 2).

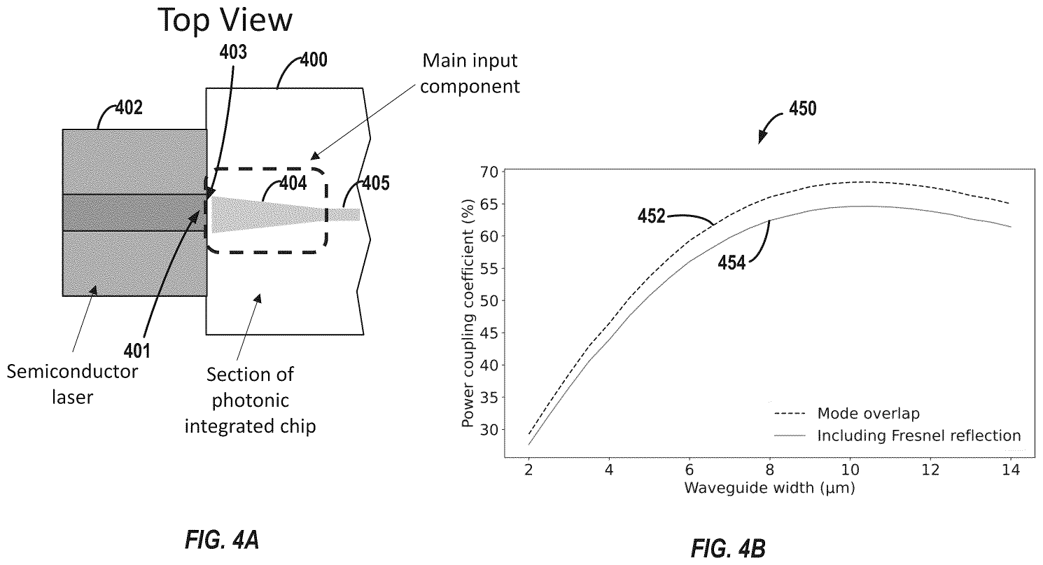

The aforementioned problem of minimizing back-reflections to the semiconductor lasers may be addressed in several ways. As in FIG. 3, the semiconductor laser output facet and the chip input facet may be placed in contact within one another, with the distance between the two being less than 1 micron. With this configuration, any back-reflection from the chip input facet is not substantially different from the back-reflection that the laser would experience standalone, and therefore the laser behavior is not fundamentally altered. This is further illustrated in FIG. 4A, which also shows a coupling portion of the photonic chip with linear taper.

FIG. 4A illustrates a top view of an exemplary embodiment of a coupling portion of the photonic chip 400 (not to scale) that uses a linear taper. The coupling portion may be used as the mode-matching component 306 of FIG. 3. As shown in FIG. 4, an output facet 401 of a semiconductor laser 402 is mounted directly to, and directly abuts, an input facet 403 of a waveguide 404 of the photonic chip 400. Waveguide 404 is tapered, as shown, to feed the laser signal into a narrower portion 405 of the waveguide, which may be coupled as shown in FIG. 3 to a user input waveguide to form the multiplexer 314 of FIG. 3.

Note that back-reflections originating from the output facet of the photonic chip can also affect the laser behavior. These back-reflections may be eliminated in various ways. In some embodiments, the back-reflections are reduced or eliminated by providing an angle between the output waveguide (e.g., waveguide 324 of FIG. 3) and an output facet of the photonic chip that deters backward guided reflections. Such angles may be obtained in different ways in different embodiments, including angled-polishing of the facet or angled-routing of the waveguide. These solutions can be combined with anti-reflective coating of the chip facets for increased reduction in the back-reflection.

FIG. 4B is a graph 450 illustrating numerical simulation values for the power coupling coefficient vs. waveguide width. That is, the graph shows how the coupling of coupler between a semiconductor laser and a nonlinear photonic chip changes with the width of the waveguide at the facet of the photonic chip. A first curve 452 corresponds to the power coupling obtained by just considering the overlap between an electromagnetic mode of the semiconductor laser and an electromagnetic mode of the waveguide. A second curve 454 further includes the effect of the Fresnel reflection due to a mismatch between the refractive indexes of the semiconductor laser and the waveguide. The information within the graph may be used to optimize a linear taper (of the type shown in FIG. 4A). In this specific example, both curves suggests that a waveguide width of about 10 μm provides the largest power coupling coefficient, so the linear taper portion 404 may be configured to change the width from the optimum of 10 μm at 403, to any desired width at 405.

FIG. 5A illustrates a top view 500 of a portion of the photonic chip showing an output waveguide 502 (which may correspond, e.g., to waveguide 324 of FIG. 3) and an output chip facet 504 of the photonic chip, which is formed at an angle relative to the surface of the photonic chip. As such, the end of the waveguide is at angle to the chip facet. FIG. 5A also provides a side cross-sectional view 506 of the photonic chip, showing its thin-film 508 formed on a substrate 510 and showing the location of the chip facet 504 at its edge.

FIG. 5B illustrates a top view 550 of a portion of another photonic chip showing an output waveguide 552 (which may correspond, e.g., to waveguide 324 of FIG. 3) and an output chip facet 554 of the photonic chip. In this example, the chip facet is formed at an angle relative to the side edge of the photonic chip. Again, the end of the waveguide is at angle to the chip facet. FIG. 5A also provides a side cross-sectional view 556 of the photonic chip, showing its thin-film 558 formed on a substrate 560 and showing the location of chip facet 554 at its edge.

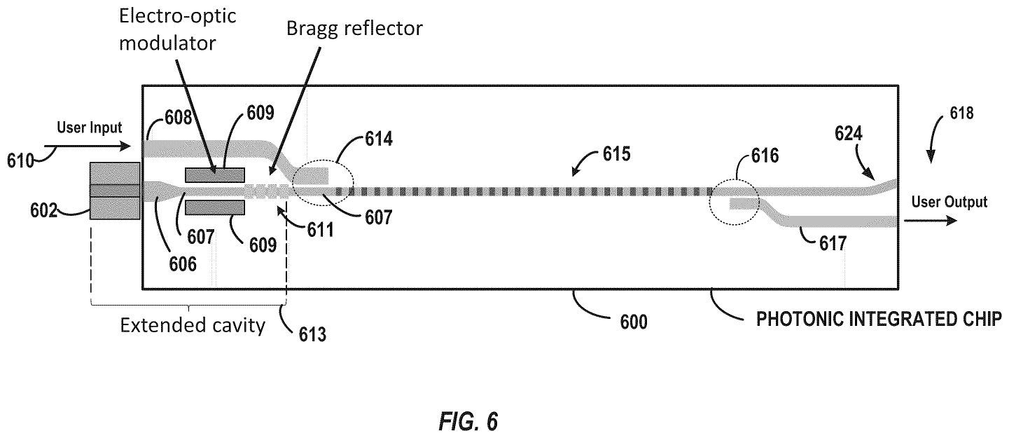

FIG. 6 illustrates an alternative version of the integrated photonic chip 300 of FIG. 3 that is modified to provide optical feedback to the semiconductor laser, rendering it as an external cavity semiconductor laser and/or a self-injection-locked tunable laser. A Bragg-reflector provides optical feedback to the semiconductor laser. Tunability can be provided by an electro-optic modulator (or by an integrated heater) that varies the optical feedback phase.

As shown in FIG. 6, the photonic chip 600 includes a semiconductor laser 602 that is mounted to a mode matching input element 606 of a waveguide 607 of the chip 600. An input optical signal is fed into waveguide 608, which serves as the external input component of the chip 600. An electro-optic modulator 609 is positioned on or near a portion of waveguide 607. A Bragg reflector 611 is provided along the waveguide 607 beyond the modulator 609. With this configuration, the cavity of the laser 602 is extended into the chip 600, as shown by way of dashed lines 613. Waveguides 607 and 608 are then coupled to form a multiplexer 614. The combined optical signal is applied to a nonlinear waveguide 615, which provides the nonlinear DFG/SFG component of the chip 600. Another waveguide 617 is coupled to nonlinear waveguide 615 at its far end to form a demultiplexer 616, which provides two or more output signals 618. Light is also output via an angled facet at the end of waveguide 624.

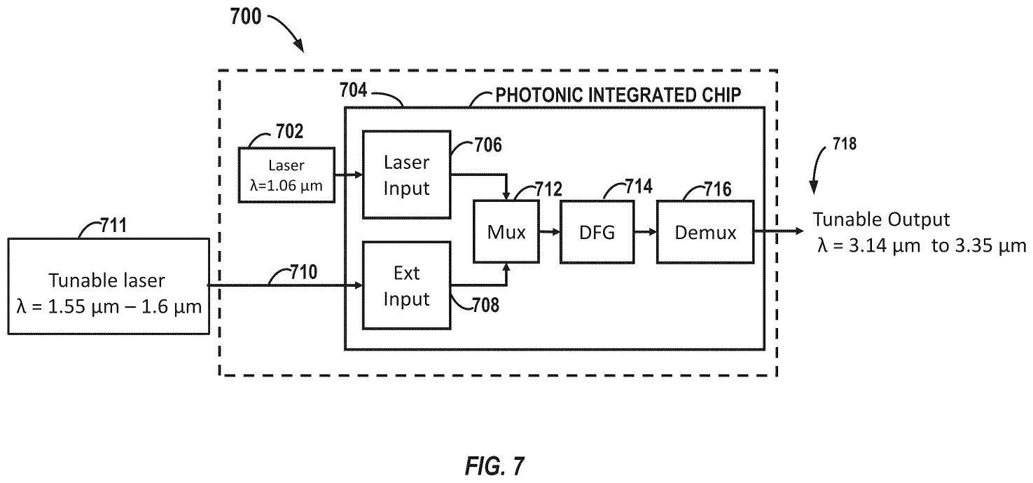

FIG. 7 illustrates an exemplary embodiment of a photonic device 700 configured for spectroscopy that uses a tunable telecom laser as an external input. Many features are similar to those of FIG. 2 and will not be described in detail. A semiconductor laser 702 is coupled to a photonic integrated chip 704. The semiconductor laser 702 may be configured to provide a coherent optical signal at, e.g., λ=1.06 μm. The photonic integrated chip 704 includes a laser input component 706 and an external input component 708, which can receive an input optical signal provided by a tunable laser 711 in the range of, e.g., Δ=1.5 μm to λ=1.6 μm. The optical signals received via laser input 706 and external input 708 are applied to a wideband optical multiplexer 712 and the resulting combined signal is applied to a DFG component 714, which may be a nonlinear waveguide configured for DFG where the waveguide is phase-matched to optimize for difference frequency generation between the semiconductor laser 702 and the tunable wavelength laser 711. The output of the nonlinear component 714 is fed into an optical demultiplexer 716, which provides a tunable output signal 718 in the range of, e.g., λ=3.14 μm to λ=3.35 μm. The output signal is tunable by controlling the tunable laser 711 using a controller (not shown). Note that output signals in the range of λ=3.14-3.35 μm (mid-range IR) are well suited for certain spectroscopic studies. The embodiment uses a tunable telecom laser, which is typically cheaper and more reliable than a laser capable of directly generating light at these mid-infrared wavelengths.

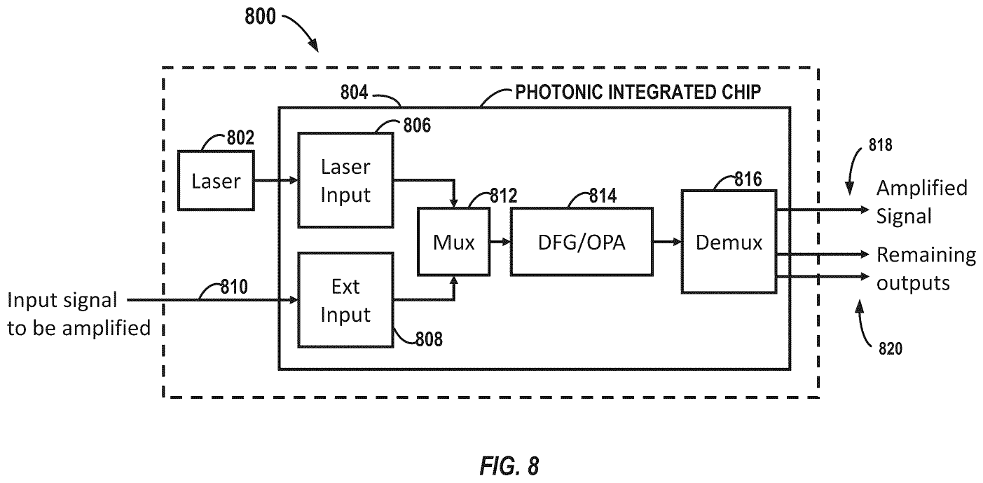

FIG. 8 illustrates an exemplary embodiment of a photonic device 800 configured for parametric amplification (e.g., optical parametric amplification (OPA)). Many features are similar to those of FIGS. 2 and 6 and will not be described in detail. A semiconductor laser 802 is coupled to a photonic integrated chip 804 that includes a laser input component 806 and an external input component 808, which can receive an input optical signal to be amplified. The optical signals received via laser input 806 and external input 808 are applied to a wideband optical multiplexer 812 and the resulting combined signal is applied to a DFG/OPA component 814, which may be a nonlinear waveguide configured for DFG/OPA. The output of the nonlinear component 814 is fed into an optical demultiplexer 816, which provides an amplified output signal 818 as well as various other outputs 820.

The external light source input signal 810 should have an optical frequency lower than the optical frequency of the semiconductor laser to produce an output wave from the DFG/OPA 816 that contains an amplified version of the signal input component. The physical process of DFG produces amplification of an input wavelength with a longer wavelength. The amplifier of FIG. 8 may be quite valuable since it can be operated at almost any wavelength, as long as the appropriate phase matching is provided in the nonlinear waveguide. Furthermore, in some embodiments, the semiconductor laser may be a low coherence device supporting several longitudinal modes. For instance, the integrated laser diode may be an inexpensive Fabry-Perot laser with several longitudinal modes with a wavelength centered near 1064 nm, while the user signal to be amplified may be a coherent telecommunication signal with a wavelength near 1550 nm. In this process, a multimode idler signal is generated with a wavelength near 3.4 microns.

The parametric amplifier of FIG. 8 may also be configured to amplify pulsed signals. For example, the laser 802 may operate in the CW regime, whereas the external light source providing signal 810 may be a pulsed laser. Indeed, the bandwidth obtainable is adjustable by dispersion engineering, i.e., by using the waveguide dimensions to modify its dispersion. (Dispersion engineering is discussed below.) This allows the amplification of extremely wideband signals, including pulses as short as a few femtoseconds.

The nonlinear waveguide 814 of FIG. 8 may be configured with a geometry designed to increase the difference between the group-velocities at the wavelength of the semiconductor laser 802 and the center wavelength of the input signal 810 of the pulsed external light source. Although not shown in FIG. 8, a resonator may be provided within the photonic chip to enhance the light input from the semiconductor laser 802. For example, a racetrack resonator may be provided, as will be described below.

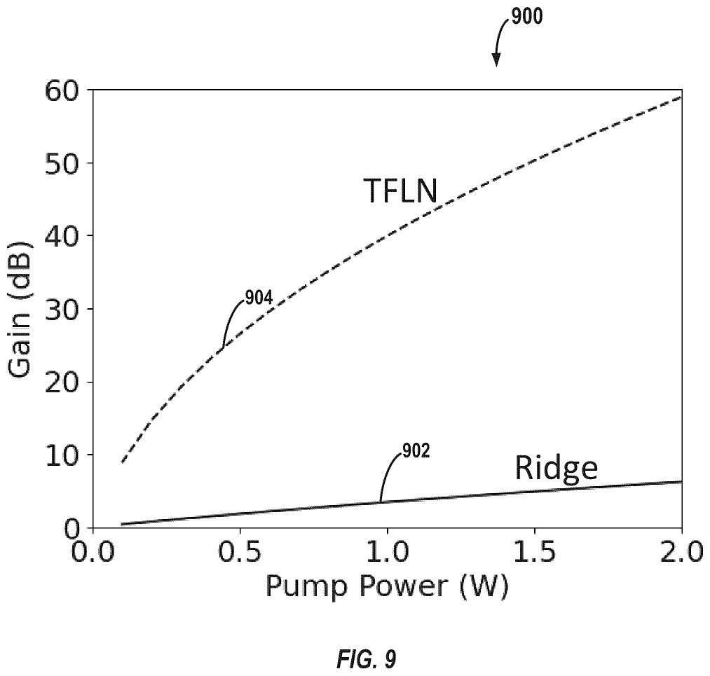

FIG. 9 is a graph 900 showing gain (in dB) for a 1-cm long amplifier as a function of pump power (in watts) for a conventional ridge waveguide optical device as represented by curve 902 and for a thin-film lithium niobate (TFLN) platform configured for parametric amplification as represented by curve 904. Note the significantly greater gain achieved with the thin-film device. The example of FIG. 9 exploits a pump resonator.

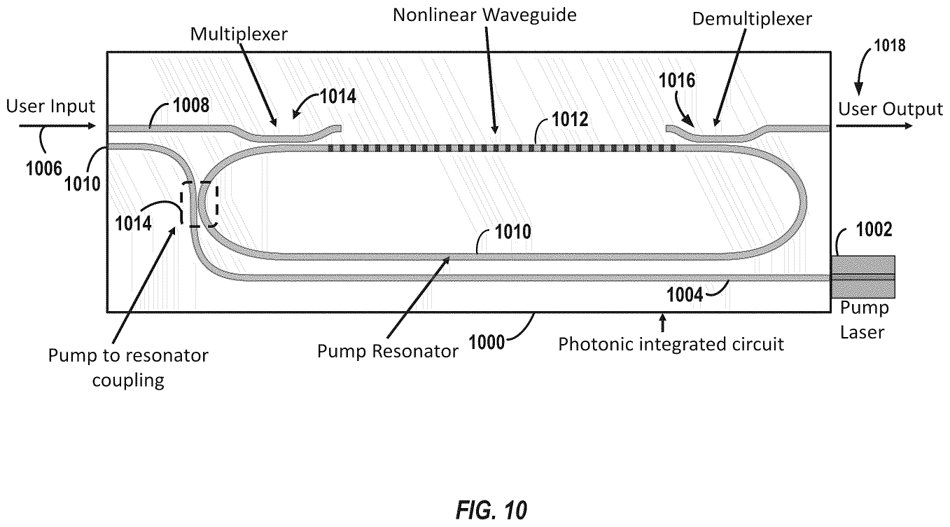

FIG. 10 is a stylized top view representation an embodiment (not to scale) of an integrated photonic chip 1000 that employs a racetrack resonator. A semiconductor pump laser 1002 is directly mounted to a waveguide 1004 of the chip 1000 (e.g., using a mode matching input element not shown). A user input optical signal 1006 is fed into a waveguide 1008. A pump resonator waveguide 1010 forms a loop within the photonic chip that includes a nonlinear waveguide portion 1012. Waveguide 1004 and waveguide 1010 are coupled at 1014 to provide pump to resonator coupling. With this configuration, a portion of light input from the pump laser 1002 is coupled into the resonator loop 1010 and then circulates within the resonator loop as more and more light is coupled into it as the pump laser 1002 continues to operate. The user input signal along waveguide 1008 is coupled into waveguide 1010 at multiplexer coupler 1014, allowing the combined optical waves to propagate through the nonlinear waveguide portion 1012 of the resonator waveguide loop 1001. A portion of the optical waves are coupled out of the resonator loop using a demultiplexer coupler 1016 for output as user output 1018. Note also that with this configuration, portions of the pump laser signal from laser 1002 that are not coupled into the pump resonator loop 1001 are emitted from the photonic chip at output facet 1020 to, e.g., prevent overheating of the chip and backscatter back into the pump laser 1002.

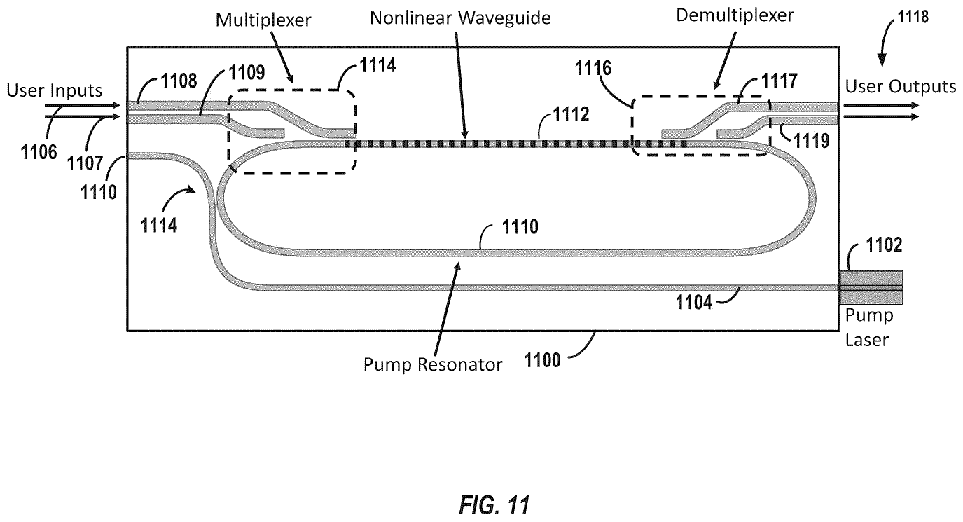

FIG. 11 is a stylized top view representation another embodiment (not to scale) of an integrated photonic chip 1100 that employs a racetrack resonator. The embodiment of FIG. 11 is similar to that of FIG. 10 but includes two user inputs and two user outputs. A semiconductor pump laser 1102 is again directly mounted to a waveguide 1104 (e.g., using a mode matching input element not shown). A first user input optical signal 1106 is fed into a waveguide 1108. A second user input optical signal 1107 is fed into a parallel waveguide 1109. A pump resonator waveguide 1110 forms a loop within the photonic chip that includes a nonlinear waveguide portion 1112. Waveguides 1104 and 1110 are coupled at 1114 to provide pump to resonator coupling so that a portion of light input from the pump laser 1102 is coupled into the resonator loop 1110 and then circulates within the resonator loop. The user input signals along waveguides 1108 and 1109 are coupled into waveguide 1110 at multiplexer coupler 1114, allowing the combined optical waves to propagate through the nonlinear waveguide portion 1112 of the resonator waveguide loop 1101. A portion of the optical waves are coupled out of the resonator loop using a demultiplexer coupler 1116 into a pair of waveguides 1117 and 1119 for output as a pair of user outputs 1118. Portions of the pump laser signal from laser 1102 that are not coupled into the pump resonator loop 1101 are emitted from the photonic chip at output facet 1120 to, e.g., prevent overheating of the chip and backscatter back into the pump laser 1102.

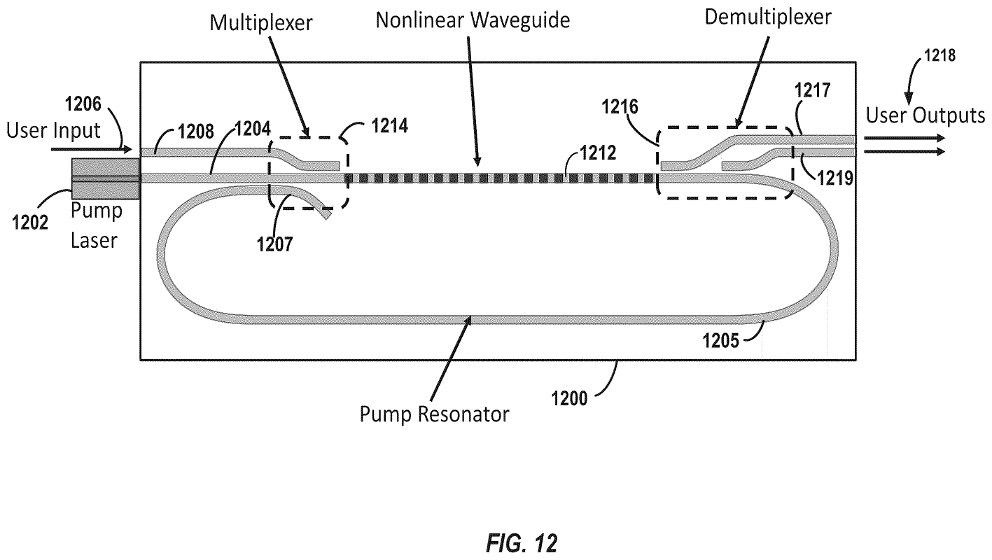

FIG. 12 is a stylized top view representation yet another embodiment (not to scale) of an integrated photonic chip 1200 that employs a racetrack resonator. The embodiment of FIG. 12 is similar to that of FIG. 10 but includes two user outputs and the semiconductor pump laser is positioned near the user input. The semiconductor pump laser 1202 is again directly mounted to a waveguide 1204 (e.g., using a mode matching input element not shown). A user input optical signal 1206 is fed into a waveguide 1208. Waveguides 1204 and 1008 are coupled at 1214 to form a portion of a multiplexer 1214 with the combined signal then propagated through a nonlinear waveguide portion 1212 into a pump resonator loop waveguide 1205. A portion 1207 of the pump resonator loop waveguide 1205 is also coupled to waveguide 1204 within multiplexer 1214 so that a portion of the signal propagating through waveguide 1205 is coupled into waveguide 1204 and then back into the nonlinear waveguide portion 1212, thus forming a pump resonator loop. A portion of the optical waves are coupled out of the resonator loop using a demultiplexer coupler 1216 into a pair of waveguides 1217 and 1219 for output as a pair of user outputs 1218.

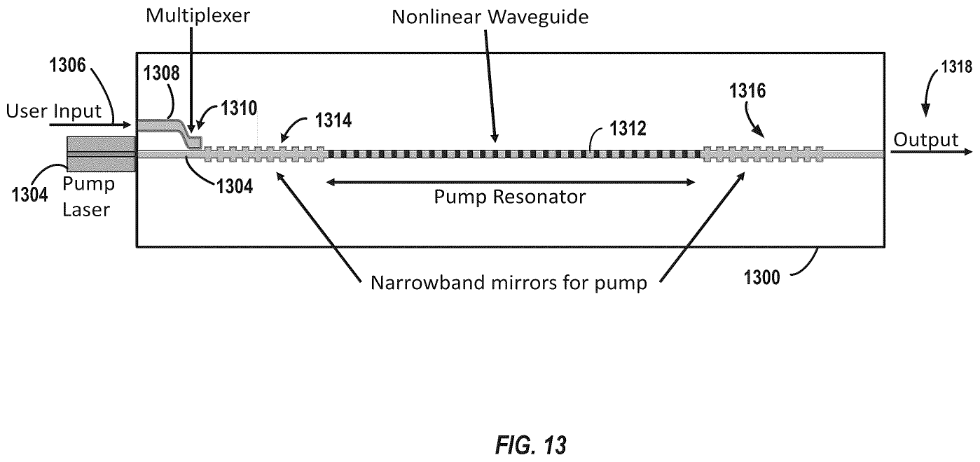

FIG. 13 is a stylized top view representation an embodiment (not to scale) of an integrated photonic chip 1300 that employs a linear resonator. A semiconductor pump laser 1302 is directly mounted to a waveguide 1304 of the chip 1300 (e.g., using a mode matching input element not shown). A user input optical signal 1306 is fed into a waveguide 1308 and coupled into waveguide 1304 at multiplexer coupler 1310, allowing the combined optical waves to propagate into a nonlinear waveguide portion 1312. A first narrow band waveguide mirror 1304 is provided at one end of the nonlinear waveguide portion 1312. A second narrow band waveguide mirror 1116 is provided at the other, second end of the nonlinear waveguide portion 1312. The portion of waveguide 1312 between the two mirrors functions as a pump resonator. With this configuration, a portion of light propagating through nonlinear waveguide portion 1312 is reflected by mirror 1316, then reflected again by mirror 1314, which serves to enhance the pump laser signal within the nonlinear waveguide portion 1312. A portion of the signal passes through mirror 1316 and exits the photonic chip as an output signal 1318.

In some embodiments, dispersion engineering is used to maximize the efficiency of parametric amplification of pulses using a CW pump. The is achieved by mismatching the group velocities of a pulsed signal (e.g., from an external laser) and the CW pump (e.g., from a pump semiconductor laser), so that a pulsed signal walks-off the CW pump as it becomes amplified, therefore always experiencing the full strength of the undepleted CW pump.

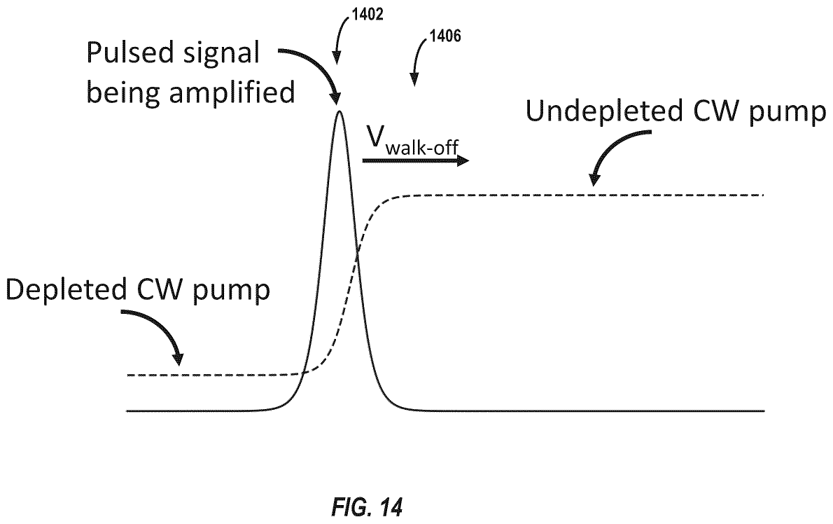

FIG. 14 illustrates the walk-off feature, which shows a pulsed signal 1400, which is amplified (as shown by peak 1402). The CW pump signal is shown by dashed lines 1404. The waveguide dimensions are engineered so that there is a mismatch between the group velocities of the CW pump signal and the pulsed signal. This makes the pulsed signal move relative to the CW pump signal. Their relative velocity, known in the literature as walk-off, is indicated by arrow 1406. The pulsed signal gets amplified by extracting energy from the CW pump signal, thus depleting it (as shown to the left of the peak 1402). The walk-off allows the pulsed signal to move into parts of the CW pump signal that have not been depleted (to the right of peak 1402), allowing the amplification process to continue.

The amplifiers disclosed herein may also be used in a phase sensitive fashion by having an external input harmonically related to the semiconductor laser, or by having two external inputs with frequencies that add up to the frequency of the semiconductor laser.

The amplifiers disclosed herein may be used in large variety of applications. For instance, the disclosed amplifiers can replace bulky fiber amplifiers used in telecommunication systems. At least some features are particularly advantageous for upcoming communication systems that employ wavelengths not typically covered by conventional amplifiers. For instance, the amplifier may be used to boost signals in fiber-based communication systems using 1310 nm or 1650 nm wavelengths, as well as in free-space communication systems using wavelengths at appropriate atmospheric transparency windows. Furthermore, the amplifiers disclosed herein can be made to be phase-sensitive, e.g. capable of amplifying only a single quadrature of the optical field. Such amplifiers can be used in future coherent communication systems employing general quadrature amplitude modulated signals (QAM). The amplifiers disclosed here can also find use in the phase-sensitive amplification of squeezed light for use in quantum optical systems. As an additional example of their broad application, the amplifiers disclosed herein can be used to enhance background-free spectroscopy.

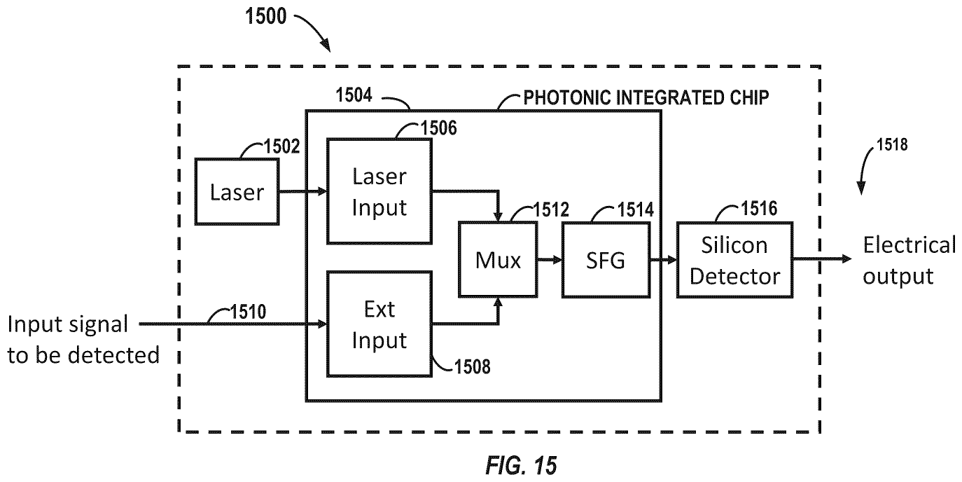

FIG. 15 illustrates an exemplary embodiment of a photonic device 1500 configured for use as an infrared (IR) detector. Many features are similar to those of FIGS. 2 and 6, and 7 and will not be described in detail. A semiconductor laser 1502 is coupled to a photonic integrated chip 1504 that includes a laser input component 1506 and an external input component 1508, which can receive an input optical signal 1510 to be detected. The optical signals received via laser input 1506 and external input 1508 are applied to a wideband optical multiplexer 1512 and the resulting combined signal is applied to an SFG component 1514, which may be a nonlinear waveguide configured for SFG. The output of the nonlinear SFG component 1514 exits the photonic chip 1504 and is fed into a detector 1516 (e.g., a silicon-based device configured to function as an IR detector). The detector 1516 outputs an electrical signal 1518, which is representative of the IR signal being detected. For example, the device of FIG. 15 may be configured to detect mid-infrared signals. However, the device may also be configured to operate with visible light. Furthermore, the signal is effectively amplified as well since the presence of the pump in the SFG process provides heterodyne gain.

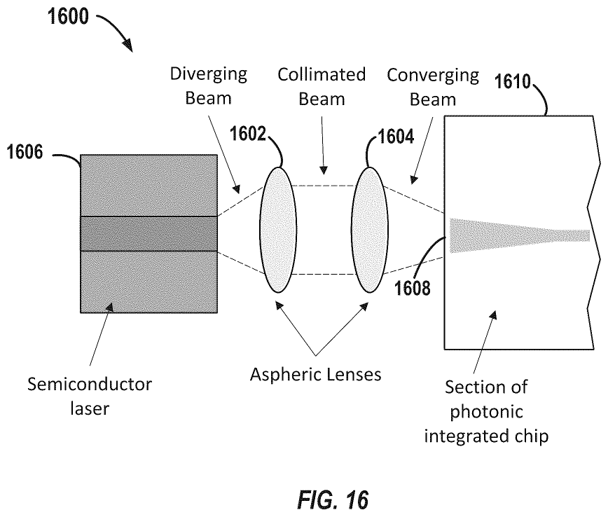

FIG. 16 illustrates a top view of an exemplary embodiment of a free-space coupling section 1600 that uses a pair of aspheric lenses to couple a semiconductor laser to an input facet of a photonic chip, in accordance with some aspects of the disclosure. Briefly, the coupling section (or coupler) 1600 includes a first aspheric lens 1602 and a second aspheric lens 1604 mounted between a semiconductor laser 1606 and an input facet 1608 of a photonic chip 1610. A diverging beam from an output facet of the laser 1606 is collimated by the first aspheric lens 1602, then focused as a converging beam into the input facet of the photonic chip 1610.

The photonic devices described herein can also be used to provide a combination of all the previously mentioned applications on a single nonlinear chip. For instance, the processes of DFG/OPA and SHG can be combined on a single waveguide by an appropriate quasi-phase matching design. If the processes are to be performed sequentially, then the waveguide can be fabricated with two different quasi-phase matching periods one after the other. If the processes are to be performed simultaneously, then the waveguide can be fabricated with an aperiodic structure optimized for that combined process. Other types of aperiodic structures are also possible, including those that increase the interaction bandwidth by continuous variations of the quasi-matching period (also known as chirping).

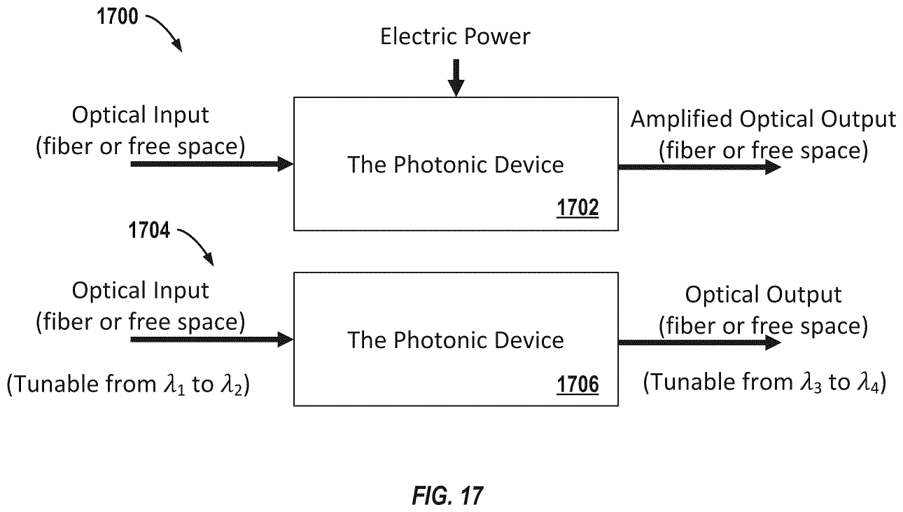

FIG. 17 broadly summarizes various applications of the photonic device. In a first general example 1700, an optical input (either from an optic fiber or free space) is applied to a photonic device 1702 that also receives electric power. The photonic device 1702 amplifies the input signal to generate an amplified optical output (either into an optic fiber or free space). In a second general example 1704, an optical input (either from an optic fiber or free space) is applied to a photonic device 1706 (that does not receive electric power). The optical input is tunable from λ₁ to λ₂. The photonic device 1702 converts the input signal into optical output signal (again either into an optic fiber or free space), where the output is tunable from λ₃ to λ₄.

### Further Exemplary Embodiments

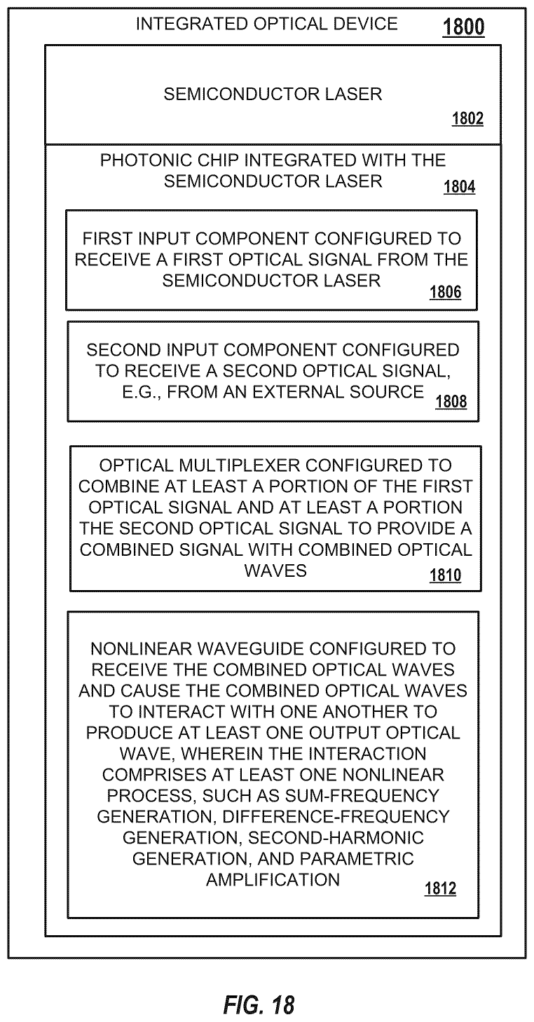

FIG. 18 is a block diagram of an exemplary embodiment of an integrated optical device 1800. The integrated optical device 1800 includes a semiconductor laser 1802 and a photonic chip 1804 integrated with the semiconductor laser. The photonic chip 1804 includes: a first input component 1806 configured to receive a first optical signal from the semiconductor laser; a second input component 1808 configured to receive a second optical signal; an optical multiplexer 1810 configured to combine at least a portion of the first optical signal and at least a portion the second optical signal to provide a combined signal with combined optical waves; and a nonlinear waveguide 1812 configured to receive the combined optical waves and cause the combined optical waves to interact with one another to produce at least one output optical wave, wherein the interaction comprises at least one nonlinear process, such as sum-frequency generation, difference-frequency generation, second-harmonic generation, and parametric amplification. The photonic chip may be a thin-film chip. Additional components may be provided, such as an optical demultiplexer, an actuator, or other components or devices, as discussed above.

In some aspects, an integrated optical device is provided that includes: means for generating a first coherent optical signal; and a photonic chip integrated with the means for generating the first coherent optical signal. The photonic chip includes: means for receiving the first coherent optical signal; means for receiving a second coherent optical signal; means for combining at least a portion of the first coherent optical signal and at least a portion the second coherent optical signal to provide a combined signal with combined optical waves; and means for causing the combined optical waves to interact with one another to produce at least one output optical wave, wherein the interaction comprises at least one nonlinear process.

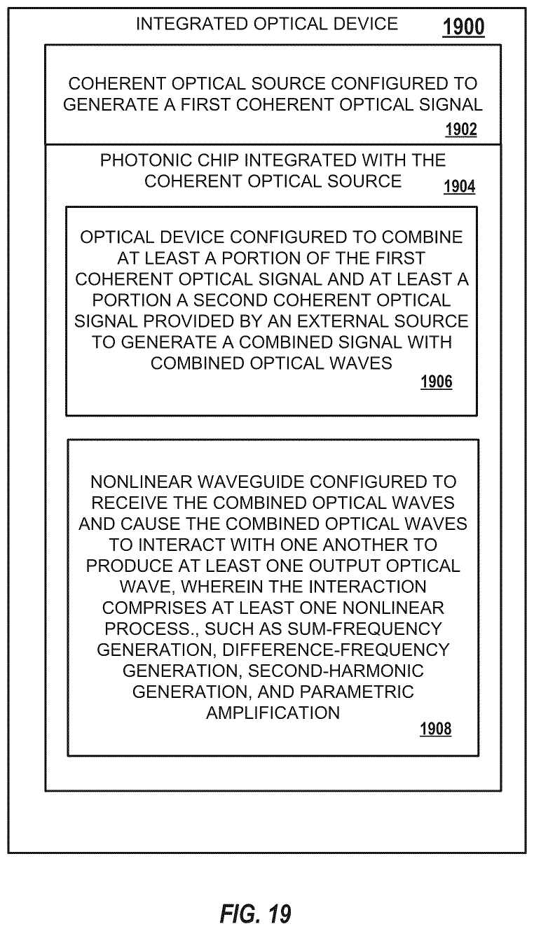

FIG. 19 is a block diagram of an exemplary embodiment of an integrated optical device 1900. The integrated optical device 1900 includes a coherent optical source 1902 configured to generate a first coherent optical signal and a thin-film photonic chip 1904 integrated with the coherent optical source 1902. The photonic chip 1904 includes: an optical device 1905 configured to combine at least a portion of the first coherent optical signal and at least a portion a second coherent optical signal provided by an external source to generate a combined signal with combined optical waves. The photonic chip 1904 also includes: a nonlinear waveguide 1908 configured to receive the combined optical waves and cause the combined optical waves to interact with one another to produce at least one output optical wave, wherein the interaction includes at least one nonlinear process, such as sum-frequency generation, difference-frequency generation, second-harmonic generation, and parametric amplification. Additional components may be provided, such as an optical demultiplexer, an actuator, or other components or devices, as discussed above.

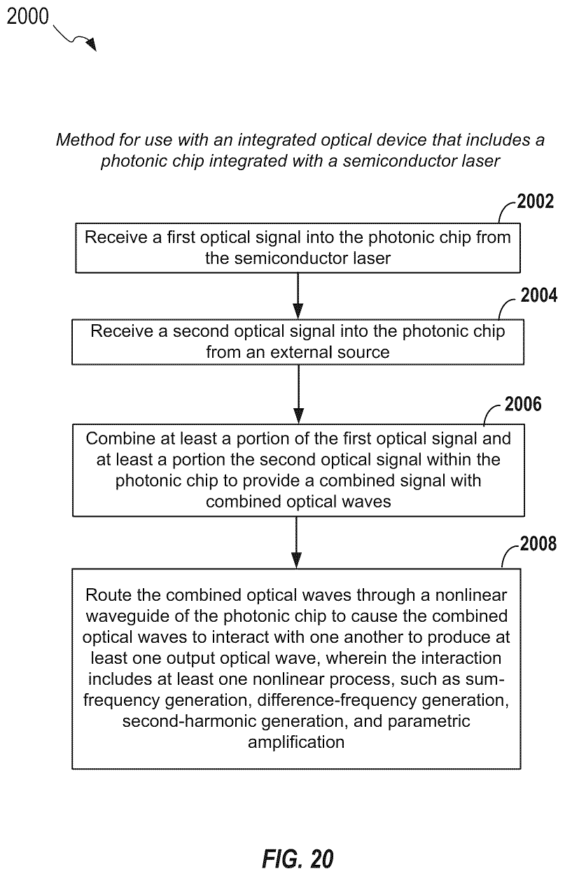

FIG. 20 is a flow diagram 2000 of an exemplary method for use with an integrated optical device that includes a thin-film photonic chip integrated with a semiconductor laser. At block 2002, the photonic chip receives a first optical signal from the semiconductor laser. At block 2004, the photonic chip receives a second optical signal from an external source. At block 2006, the photonic chip combines at least a portion of the first optical signal and at least a portion the second optical signal within the photonic chip to provide a combined signal with combined optical waves. At block 2008, the photonic chip routes the combined optical waves through a nonlinear waveguide of the photonic chip to cause the combined optical waves to interact with one another to produce at least one output optical wave, wherein the interaction includes at least one nonlinear process, such as sum-frequency generation, difference-frequency generation, second-harmonic generation, and parametric amplification. Additional operations may be performed as well.

### Additional Aspects

The examples set forth herein are provided to illustrate certain concepts of the disclosure. The apparatus, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of other aspects and that two or more of these aspects may be combined in various ways. For example, an apparatus may be implemented or a method may be practiced using any number of the aspects set forth herein. In some cases, such an apparatus may be implemented or such a method may be practiced using other structures or functionalities in addition to or other than one or more of the aspects set forth herein.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage, or mode of operation.

While the above descriptions contain many specific embodiments of the invention, these should not be construed as limitations on the scope of the invention, but rather as examples of specific embodiments thereof. Accordingly, the scope of the invention should be determined not by the embodiments illustrated, but by the appended claims and their equivalents. Moreover, reference throughout this specification to “one embodiment,” “an embodiment,” “in one aspect,” or similar language means that a particular feature, structure, or characteristic described in connection with the embodiment is included in at least one embodiment of the present disclosure. Thus, appearances of the phrases “in one embodiment,” “in an embodiment,” “in one aspect,” and similar language throughout this specification may, but do not necessarily, all refer to the same embodiment, but mean “one or more but not all embodiments” unless expressly specified otherwise.

If used herein, the term “determining” encompasses a wide variety of actions. For example, “determining” may include calculating, computing, processing, deriving, investigating, looking up (e.g., looking up in a table, a datastore, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The terminology used herein is for the purpose of describing particular aspects only and is not intended to be limiting of the aspects. As used herein, the singular forms “a,” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises,” “comprising,” “includes” “including,” “having,” and variations thereof when used herein mean “including but not limited to” unless expressly specified otherwise. That is, these terms may specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of A, B, or C” or “A, B, C, or any combination thereof” or “one or more of A, B, or C” used in the description or the claims means “A or B or C or any combination of these elements.” For example, this terminology may include A, or B, or C, or A and B, or A and C, or A and B and C, or 2A, or 2B, or 2C, or 2A and B, and so on. As a further example, “at least one of: A, B, or C” or “one or more of A, B, or C” is intended to cover A, B, C, A-B, A-C, B-C, and A-B-C, as well as multiples of the same members (e.g., any lists that include AA, BB, or CC). Likewise, “at least one of: A, B, and C” or “one or more of A, B, or C” is intended to cover A, B, C, A-B, A-C, B-C, and A-B-C, as well as multiples of the same members. Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An integrated optical device, comprising:
a semiconductor laser; and
a photonic chip integrated with the semiconductor laser, the photonic chip comprising:
a first input component configured to receive a first optical signal from the semiconductor laser;
a second input component configured to receive a second optical signal;
an optical multiplexer configured to combine at least a portion of the first optical signal and at least a portion the second optical signal to provide a combined signal with combined optical waves; and
a nonlinear waveguide configured to receive the combined optical waves and cause the combined optical waves to interact with one another to produce at least one output optical wave, wherein the interaction comprises at least one nonlinear process.

2. The integrated optical device of claim 1, wherein the nonlinear process comprises one or more of sum-frequency generation, difference-frequency generation, second-harmonic generation, and parametric amplification.

3. The integrated optical device of claim 1, wherein the first input component of the photonic chip comprises an input facet, with an output facet of the semiconductor laser mounted directly to the input facet.

4. The integrated optical device of claim 1, further comprising a free-space coupling section configured to couple an output facet of the semiconductor laser to an input facet of the photonic chip, the free-space coupling section comprising one or more lenses and mirrors.

5. The integrated optical device of claim 1, wherein the input facet of the photonic integrated chip comprises one or more of: an input waveguide formed at an angle; an input facet with an anti-reflection coating; and an angle-polished input facet.

6. The integrated optical device of claim 1, wherein the photonic chip further comprises one or more of: a wideband optical multiplexer, a mode-size converter, and a mode filter.

7. The integrated optical device of claim 1, wherein an output facet of the photonic integrated chip comprises one or more of: an output waveguide formed at an angle; an output facet with an anti-reflection coating; and an angle-polished output facet.

8. The integrated optical device of claim 1, wherein the first input component comprises a grating coupler, and wherein an output facet of the semiconductor laser is mounted in close proximity to the grating coupler.

9. The integrated optical device of claim 1, wherein the photonic chip further comprises an optical demultiplexer configured to separate an output wave from the nonlinear waveguide into a plurality of outputs having different wavelengths.

10. The integrated optical device of claim 1, wherein the nonlinear waveguide is configured to employ quasi-phase matching using one or more of periodic poling, aperiodic poling, and orientation patterning.

11. The integrated optical device of claim 1, further comprising an actuator configured to control phase-matching within the nonlinear waveguide using one or more of heat modulation and electro-optic modulation.

12. The integrated optical device of claim 1, wherein the nonlinear waveguide has a geometry configured with an optical dispersion sufficient to accommodate a range of wavelengths that can be input to the first input component.

13. The integrated optical device of claim 1, wherein the nonlinear waveguide is configured to have a second-order nonlinear coefficient that may be induced by an electric field.

14. The integrated optical device of claim 1, wherein the semiconductor laser is configured to operate in a continuous wave (CW) regime.

15. The integrated optical device of claim 1, wherein the semiconductor laser is configured to operate in a pulsed regime.

16. The integrated optical device of claim 1, wherein the semiconductor laser is configured to be tunable to enable tuning of an output of the photonic chip.

17. The integrated optical device of claim 1, wherein the photonic chip further comprises a resonator configured to enhance the first optical signal from the semiconductor laser.

18. The integrated optical device of claim 1, wherein the second optical signal has an optical frequency lower than an optical frequency of the first optical signal from the semiconductor laser, and wherein the output optical wave contains an amplified version of the second optical signal.

19. The integrated optical device of claim 18, wherein the photonic chip further comprises a resonator configured to enhance the first optical signal from the semiconductor laser.

20. The integrated optical device of claim 1, wherein the semiconductor laser is configured to operate in the continuous wave (CW) regime and wherein the second optical signal is a pulsed laser signal.

21. The integrated optical device of claim 20, wherein the second optical signal is provided by a pulsed external light source, and wherein the nonlinear waveguide has a geometry configured to increase a difference between group-velocities at a wavelength of the semiconductor laser and at a center wavelength of the pulsed external light source.

22. The integrated optical device of claim 1,
wherein the second optical signal is provided by an external tunable wavelength semiconductor laser; and
wherein the nonlinear waveguide is phase-matched to enable difference frequency generation between the semiconductor laser and the tunable wavelength semiconductor laser.

23. The integrated optical device of claim 1,
wherein the second optical signal represents an unknown signal to be detected that has a wavelength longer than the wavelength of the semiconductor laser,
wherein the nonlinear waveguide is phase-matched to enable sum frequency generation between the semiconductor laser and the unknown signal to be detected, and
wherein a visible or near-infrared photodetector is coupled to the output of the photonic chip to detect the sum frequency signal generated in the nonlinear waveguide to enable infrared signal detection.

24. The integrated optical device of claim 1, further comprising a second semiconductor laser, wherein the second input component is configured to receive the second optical signal from the semiconductor laser.

25. The integrated optical device of claim 1, wherein a cavity of the semiconductor laser is extended to the photonic chip.

26. A method for use with an integrated optical device that includes a photonic chip integrated with a semiconductor laser, the method comprising:
receiving a first optical signal into the photonic chip from the semiconductor laser;
receiving a second optical signal into the photonic chip from an external source;
combining at least a portion of the first optical signal and at least a portion the second optical signal within the photonic chip to provide a combined signal with combined optical waves; and
routing the combined optical waves through a nonlinear waveguide of the photonic chip to cause the combined optical waves to interact with one another to produce at least one output optical wave, wherein the interaction comprises at least one nonlinear process.

27. An integrated optical device, comprising:
a coherent optical source configured to generate a first coherent optical signal; and
a photonic chip integrated with the coherent optical source, the photonic chip comprising:
an optical device configured to combine at least a portion of the first coherent optical signal and at least a portion a second coherent optical signal provided by an external source to generate a combined signal with combined optical waves; and
a nonlinear waveguide configured to receive the combined optical waves and cause the combined optical waves to interact with one another to produce at least one output optical wave, wherein the interaction comprises at least one nonlinear process.
